(19) United States
(12) Patent Application Publication
(10) Pub. No.: US 2010/0086681 A1
(43) Pub. Date: Apr. 8, 2010

(54) CONTROL DEVICE OF EVAPORATING APPARATUS AND CONTROL METHOD OF EVAPORATING APPARATUS

(75) Inventors: Hiroyuki Ikuta, Hyogo (JP); Noriaki Fukiage, Hyogo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/530,028

(22) PCT Filed: Feb. 27, 2008
(86) PCT No.: PCT/JP2008/053401

§ 371 Date: Sep. 4, 2009

(30) Foreign Application Priority Data
Mar. 6, 2007 (JP) 2007-055774

(51) Int. Cl. C23C 16/52; C23C 16/00

(52) U.S. Cl. 427/248.1; 118/696

(57) ABSTRACT

Provided is a control device of an evaporating apparatus performing a film forming process on a substrate with a film forming material evaporated from a vapor deposition source, and a storage of the control device stores a plurality of tables each showing a relationship between a deposition rate and a flow rate of a carrier gas. A table selection unit selects a desired table from the plurality of tables stored in the storage based on a processing condition. A deposition controller calculates a deposition rate based on a signal outputted from a QCM. A carrier gas controller controls the flow rate of the carrier gas to obtain a desired deposition rate based on a difference between a target deposition rate and the deposition rate obtained by the deposition controller, with reference to data indicating the relationship between the deposition rate and the flow rate of the carrier gas.

### TECHNICAL FIELD

The present invention relates to a control device of an evaporating apparatus and a control method of the evaporating apparatus, and particularly, to a deposition rate control of the evaporating apparatus.

### BACKGROUND ART

Widely employed in a manufacturing process of an electronic device such as a flat panel display is an evaporating technology for forming a film on a target object by adhering film forming molecules, which are evaporated from a predetermined film forming material, to the target object. Among various types of devices manufactured by using this evaporating technology, an organic EL display and a liquid crystal display are attracting high attention particularly in the field of manufacture of the flat panel display which is expected to be scaled-up or in the field of manufacture of mobile devices for which an increasing demand is expected from now on.

In such a technical background, when manufacturing the devices by using the evaporating technology, it is important to accurately control a deposition rate (D/R) for the target object in order to uniformly form a good quality film on the target object and to thereby improve a product performance. For this reason, conventionally, it has been suggested that a film thickness sensor is installed in the vicinity of a substrate and a temperature of a vapor deposition source is controlled based on a result detected by the film thickness sensor such that a deposition rate becomes uniform (see, for example, Japanese Patent Laid-open Publication No. 2005-325425).

### DISCLOSURE OF THE INVENTION

### Problems to Be Solved by the Invention

However, in case of controlling a deposition rate by adjusting a temperature, it takes several tens of seconds or longer for a vapor deposition source to actually have a desired temperature after being heated, and thus responsiveness becomes poor. This poor responsiveness to the temperature control is caused by a heat capacity of the vapor deposition source itself or a specific heat of a film forming material, and it is also caused by a poor heat transfer condition until a heat generated from a heater changes a temperature of the film forming material.

Further, even if a temperature of the vapor deposition source reaches the desired temperature after several tens of seconds by the temperature control, it takes more time for the film forming material in the vapor deposition source to be stably evaporated at a desired vaporization rate. Accordingly, it is difficult to accurately control the deposition rate due to such a poor responsiveness.

Meanwhile, as another method for controlling a deposition rate, it can be considered that a valve is installed at a connection pipe for connecting a vapor deposition source which vaporizes a film forming material with a blowing opening which blows the evaporated film forming material, and an amount of film forming molecules blown from the blowing opening can be controlled by controlling an opening degree of the valve.

However, this method requires a high cost for preparing a vacuum valve having a high-temperature resistance since an evaporating apparatus needs to be maintained in a vacuum state. Further, an inside of the valve has a complicate structure, and it is difficult to maintain a temperature of the inside of the valve to be a certain temperature uniformly. Furthermore, it becomes difficult to accurately control the deposition rate due to a hysteresis of the valve.

In particular, in a case where the film forming material is a sublimation material (i.e., a case where a solid material is evaporated without becoming a liquid within the vapor deposition source), the state of the film forming material stored in the vapor deposition source may be changed suddenly several times during its vaporization in the vapor deposition source in comparison to a case where the film forming material is a melting material (i.e., a case where a solid material is melted into a liquid within the vapor deposition source and then evaporated). In this case, a contact state between the vapor deposition source and the film forming material is rapidly changed, so that a vaporization rate of the film forming material is suddenly changed, resulting in a sudden change in the deposition rate. However, in the method for controlling the deposition rate by the temperature control, it is difficult to quickly follow-up a small change in the deposition rate due to the poor responsiveness as described above. Therefore, by the temperature control, it is difficult to accurately control the deposition rate of the sublimation material, which is generally used as an organic EL material.

To solve the above-mentioned problems, the present invention provides an apparatus for controlling an evaporating apparatus and a method for controlling the evaporating apparatus capable of accurately controlling a deposition rate.

### Means for Solving the Problems

In accordance with one aspect of the present invention, there is provided a control device of an evaporating apparatus in which a film forming material evaporated from a vapor deposition source is transported by a carrier gas and a film forming process is performed on a target object by the transported film forming material in a desired vacuum state. The control device of the evaporating apparatus includes: a storage that stores a table indicating a relationship between a deposition rate and a flow rate of the carrier gas; a deposition rate calculation unit that calculates a deposition rate for the target object based on a signal outputted from a first sensor for detecting a deposition rate; and a carrier gas controller that controls a flow rate of the carrier gas to obtain a desired deposition rate based on a target deposition rate and the deposition rate obtained by the deposition rate calculation unit, with reference to data indicating a relationship between a deposition rate and a flow rate of the carrier gas shown in the table stored in the storage.

Here, the term “vaporization” or “evaporation” implies not only the phenomenon that a liquid is converted into a gas but also a phenomenon that a solid is directly converted into a gas without becoming a liquid (i.e., sublimation).

With this configuration, the deposition rate for the target object is measured in real time based on the signal outputted from the first sensor such as a QCM (Quartz Crystal Microbalance). Further, the table stores the data indicating the relationship between the deposition rate and the flow rate of the carrier gas. The data are obtained from information on the correlation between the deposition rate and the flow rate of the carrier gas, and the information are obtained through repeated experiments by the inventors. Based on the target deposition rate and the calculated deposition rate, the flow rate of the carrier gas is controlled to obtain a desired deposition rate with reference to the information stored in the table.

The deposition rate controlled by adjusting the flow rate of the carrier gas has a better responsiveness than that by adjusting the temperature. Therefore, the deposition rate can be accurately controlled to be a desired rate. Accordingly, a good quality film can be formed uniformly on the target object.

A nonreactive gas such as an argon gas, a helium gas, a krypton gas or a xenon gas is desirably used as the carrier gas. Further, in the above-mentioned evaporating apparatus, an organic EL film or an organic metal film may be formed on the target object by a vapor deposition by using an organic EL film forming material or an organic metal film forming material as the film forming material.

In particular, the organic EL material has a low heat-resistance and thus easily decomposed. For example, even if a temperature of the vapor deposition source is raised only by 10° C. from 250° C. to increase a deposition rate, many kinds of organic EL materials are decomposed and their properties are changed, so that a desired performance thereof can not be obtained. However, according to the above-described configuration, the deposition rate can be controlled by adjusting the flow rate of the carrier gas with reference to the correlation between the deposition rate and the flow rate of the carrier gas as stated above. Accordingly, since there is no need to raise the temperature to control the deposition rate, the deposition rate can be accurately controlled to be a desired rate without changing the property of the film forming material. Accordingly, a good quality film can be formed on the target object.

At this time, the flow rate of the carrier gas may be controlled by using a mass flow controller. In this case, there is no need for a new device such as a vacuum valve having a high-temperature resistance, so that the mass flow controller already connected to the gas supply source may be used for the film forming process. Accordingly, the deposition rate can be accurately controlled without a risk of a high cost problem which can be caused when the number of the required parts is increased or a risk of a re-condensation of the film forming molecules in the valve, which can be caused when the amount of the film forming molecules is controlled by using the valve.

The storage may store a plurality of different tables, a table selection unit that selects a desired table from the plurality of tables stored in the storage based on a processing condition may be further provided, and the carrier gas controller may control a flow rate of the carrier gas, with reference to the table selected by the table selection unit. In this case, the processing condition may include at least one of a shape of the vapor deposition source, a material of the vapor deposition source, a kind of a film forming material stored in the vapor deposition source and a position of the film forming material stored in the vapor deposition source.

The correlation between the deposition rate and the flow rate of the carrier gas may vary depending on the processing condition such as the shape or the material of the vapor deposition source, a kind of the film forming material stored in the vapor deposition source, or a position of the film forming material stored in the vapor deposition source. Taking this into consideration, the correlation between the deposition rate and the flow rate of the carrier gas depending on the processing condition is obtained in advance through experiments and stored in a plurality of tables. Then, a desired table is selected from the plurality of different tables stored in the storage based on the processing condition, and the flow rate of the carrier gas is controlled with reference to the correlation between the deposition rate and the flow rate of the carrier gas stored in the selected table.

In this way, an optimum table, which corresponds to a shape or a material of the vapor deposition source actually used in the manufacturing process and a kind or a position of the film forming material actually stored in the vapor deposition source, is selected from pre-stored data. Accordingly, a control of the flow rate of the carrier gas can be optimized depending on the processing condition actually applied in the manufacturing process, and thus the deposition rate can be controlled more accurately.

The carrier gas controller may control a deposition rate by adjusting a flow rate of the carrier gas if a difference between the target deposition rate and the deposition rate obtained by the deposition rate calculation unit is smaller than a predetermined threshold value.

Further, the control device may further include: a temperature controller that controls a temperature of the evaporating apparatus; and a film thickness control switching unit that switches a control of a deposition rate to a control using the carrier gas controller or a control using both the carrier gas controller and the temperature controller, and the film thickness control switching unit may switch a control of a deposition rate to a control using the temperature controller to adjust a temperature of the evaporating apparatus and the carrier gas controller to adjust a flow rate of the carrier gas if the difference between the target deposition rate and the deposition rate obtained by the deposition rate calculation unit is equal to or greater than the predetermined threshold value.

After conducting the experiments, the inventors found out that if there is a small difference between the target deposition rate and the calculated deposition rate, it is desirable to control the flow rate of the carrier gas with reference to the correlation between the deposition rate and the flow rate of the carrier gas, considering the responsiveness. On the other hand, the inventors found out that if there is a large difference therebetween, it is difficult to appropriately control the deposition rate to be the target deposition rate by adjusting only the flow rate of the carrier gas, so that it is desirable to control the deposition rate by adjusting both the temperature and the flow rate of the carrier gas.

Taking the above-results into consideration, if the difference in the deposition rates is small (for example, about 5 times), the deposition rate can be controlled by adjusting the flow rate of the carrier gas. Thus, the deposition rate can be accurately controlled by following-up a small change in the deposition rates. On the other hand, if the difference in the deposition rates is large (for example, about 10 to 100 times), the deposition rate can be controlled by adjusting the temperature (or both the temperature and the flow rate of the carrier gas) in combination with other adjustment. Thus, the deposition rate can be accurately controlled by following-up a great change in the deposition rates. In this way, the control of the temperature and the control of the flow rate of the carrier gas are switched depending on the degree of the change in the deposition rates. Therefore, the deposition rate can be accurately controlled according to a great change or a small change in the deposition rates.

Further, an example of a temperature control device for controlling a temperature installed at the evaporating apparatus may be a heater embedded in a bottom wall of the vapor deposition source. As an example of a method for controlling the temperature using the heater, there may be a method in which the heater is heated by controlling a voltage applied from a temperature controller based on a signal from a temperature sensor such as a thermocouple installed in the vapor deposition source. As a result, a vaporization rate of the film forming material can be controlled depending on the heating degree on a portion where the film forming material is stored.

A plurality of vapor deposition sources may be installed, the deposition rate calculation unit may calculate respective vaporization rates of a plurality of film forming materials based on signals outputted from a plurality of second sensors for respectively detecting the vaporization rates of the film forming materials stored in the plurality of vapor deposition sources in a desired vacuum state, and the carrier gas controller may control, for each vapor deposition source, a flow rate of the carrier gas introduced into each vapor deposition source based on a target vaporization rate and a vaporization rate of each film forming material obtained by the deposition rate calculation unit, with reference to data indicating a relationship between a deposition rate and a flow rate of the carrier gas shown in the table stored in the storage.

As described above, in a case where the film forming material is a sublimation material, the state of the film forming material stored in the vapor deposition source may be changed suddenly during its vaporization in the vapor deposition source, as compared to a case where the film forming material is a melting material. In this case, a contact state between the vapor deposition source and the film forming material is suddenly changed, so that the vaporization rate of the film forming material is changed, resulting in a change of the deposition rate.

However, in accordance with the above-described configuration, the flow rate of the carrier gas introduced into each vapor deposition source is controlled for each vapor deposition source based on the target vaporization rate and the vaporization rate for each film forming material stored in the plurality of vapor deposition sources arranged in the evaporating apparatus. Accordingly, the vaporization rate of the film forming material can be accurately controlled for each vapor deposition source depending on a storing state of the film forming material. As a result, a good quality film can be formed uniformly on the target object.

However, if the first sensor for detecting the deposition rate is installed, the plurality of second sensors for detecting the vaporization rate for each vapor deposition source may not be installed. In this case, the deposition rate can be obtained from the signal detected by the first sensor, and the flow rate of the carrier gas supplied to each of the plurality of vapor deposition sources is controlled uniformly based on the obtained deposition rate and the target vaporization rate. Accordingly, in comparison to a case where the flow rate of the carrier gas is controlled for each vapor deposition source using the second sensor, this configuration has some advantages in that there is no need for installing the second sensor; there is no need of maintenance for removing adhered substances deposited on the second sensor; and a control of the deposition rate is not complicated.

Further, in accordance with another aspect of the present invention, there is provided a control device of an evaporating apparatus in which a film forming material evaporated from a vapor deposition source is transported by a carrier gas and a film forming process is performed on a target object by the transported film forming material in a desired vacuum state. The control device includes a deposition rate calculation unit that calculates a deposition rate for the target object based on a signal outputted from a first sensor for detecting a deposition rate; and a carrier gas controller that feedback-controls a flow rate of the carrier gas to obtain a desired deposition rate based on a deposition rate obtained one time before (or two or more times before) by the deposition rate calculation unit and a deposition rate obtained at the present time by the deposition rate calculation unit.

With this configuration, the flow rate of the carrier gas can be accurately controlled by the feedback-control, and thus a desired deposition rate can be achieved. Further, a feedback control such as a PID (Proportional Integral Derivative) control, a fuzzy control or an H∞ (H-infinity) control may be used.

Further, in accordance with another aspect of the present invention, there is provided a control device of an evaporating apparatus in which a film forming material evaporated from a vapor deposition source is transported by a carrier gas and a film forming process is performed on a target object by the transported film forming material in a desired vacuum state. The control device includes: a storage that stores a table indicating a relationship between a deposition rate and a flow rate of the carrier gas; a deposition rate calculation unit that calculates a deposition rate for the target object based on a signal outputted from a first sensor for detecting a deposition rate; and a carrier gas controller that feedback-controls a flow rate of the carrier gas to obtain a desired deposition rate based on a deposition rate obtained one time before (or two or more times before) by the deposition rate calculation unit and a deposition rate obtained at the present time by the deposition rate calculation unit, with reference to data indicating a relationship between a deposition rate and a flow rate of the carrier gas shown in the table stored in the storage.

With this configuration, the flow rate of the carrier gas is controlled based on the deposition rate obtained one time before (or two or more times before) and the deposition rate obtained at the present time, with reference to the relationship between the deposition rate and the flow rate of the carrier gas shown in the table. Accordingly, it is possible to feedback-control the flow rate of the carrier gas based on, for example, a difference between the deposition rate calculated previously and the deposition rate calculated at the present time, with reference to pre-stored data indicating the correlation between the deposition rate and the flow rate of the carrier gas. As a result, a good quality film can be uniformly formed on the target object by accurately controlling the deposition rate to be a desired rate.

Further, in accordance with another aspect of the present invention, there is provided a control method of an evaporating apparatus in which a film forming material evaporated from a vapor deposition source is transported by a carrier gas and a film forming process is performed on a target object by the transported film forming material in a desired vacuum state. The control method includes: storing, in a storage, a table indicating a relationship between a deposition rate and a flow rate of the carrier gas; calculating a deposition rate for the target object based on a signal outputted from a first sensor for detecting a vaporization rate of the film forming material; and controlling a flow rate of the carrier gas to obtain a desired deposition rate based on the calculated deposition rate and a target deposition rate, with reference to data indicating a relationship between a deposition rate and a flow rate of the carrier gas shown in the table stored in the storage.

In this way, the flow rate of the carrier gas is controlled based on the target deposition rate and the calculated deposition rate with reference to the relationship between the deposition rate and the flow rate of the carrier gas shown in the table. As a result, since the responsiveness is better as compared to the temperature control, the deposition rate can be accurately controlled. Accordingly, a good quality film can be uniformly formed on the target object.

### EFFECT OF THE INVENTION

As described above, in accordance with the present invention, a deposition rate can be accurately controlled.

### BRIEF DESCRIPTION OF THE DRAWINGS

FIG. 1 is a schematic configuration view of a 6-layer consecutive film forming system in accordance with a first embodiment of the present invention;

FIG. 2 is view for describing a film formed by a 6-layer consecutive film forming process in accordance with each embodiment;

FIG. 3 is a schematic view of an experimental apparatus used in Experiment 1;

FIG. 4 is a graph showing a relationship between a flow rate of a carrier gas and a deposition rate as a result of Experiment 1;

FIG. 5 is a schematic view of an experimental apparatus used in Experiments 2 and 3;

FIG. 6 is a graph showing a relationship between a flow rate of a carrier gas and a deposition rate as a result of Experiment 2;

FIG. 7 is a graph showing a relationship between a flow rate of a carrier gas and a deposition rate as a result of Experiment 3;

FIG. 8 is a function block diagram illustrating each function of a controller 700 in accordance with each embodiment;

FIG. 9 is a graph showing a relationship between a temperature within a vapor disposition source and a deposition rate in accordance with each embodiment;

FIG. 10 is another graph showing a relationship between a temperature within a vapor disposition source and a deposition rate in accordance with each embodiment;

FIG. 11 is a flowchart showing a table selection process in accordance with each embodiment;

FIG. 12 is a flowchart showing a deposition rate controlling process in accordance with each embodiment;

FIG. 13 is a graph showing a change in a flow rate of a gas and a follow-up state of a deposition rate; and

FIG. 14 is a schematic configuration view of a 6-layer consecutive film forming system in accordance with a second embodiment of the present invention.

### EXPLANATION OF CODES

10: 6-layer consecutive film forming system
100: Evaporating apparatus
110: Vapor deposition source
140: Blowing device
170: First processing chamber
180, 185: QCM
190: Second processing chamber
200: Deposition controller
300: Mass flow controller
600: Temperature controller
700: Controller
710: Storage
730: Deposition rate difference calculating unit
740: Film thickness control switching unit
750: Table selection unit
760: Carrier gas controller
770: Temperature controller

### BEST MODE FOR CARRYING OUT THE INVENTION

Hereinafter, embodiments of the present invention will be described in detail with reference to the accompanying drawings. Further, parts having the same configurations and functions will be assigned like reference numerals in the following description and the accompanying drawings, and redundant description thereof will be omitted. Further, in the present document, it is assumed that 1 mTorr is (10⁻³×101325/760) Pa, and 1 sccm is (10⁻⁶/60) m³/sec.

### First Embodiment

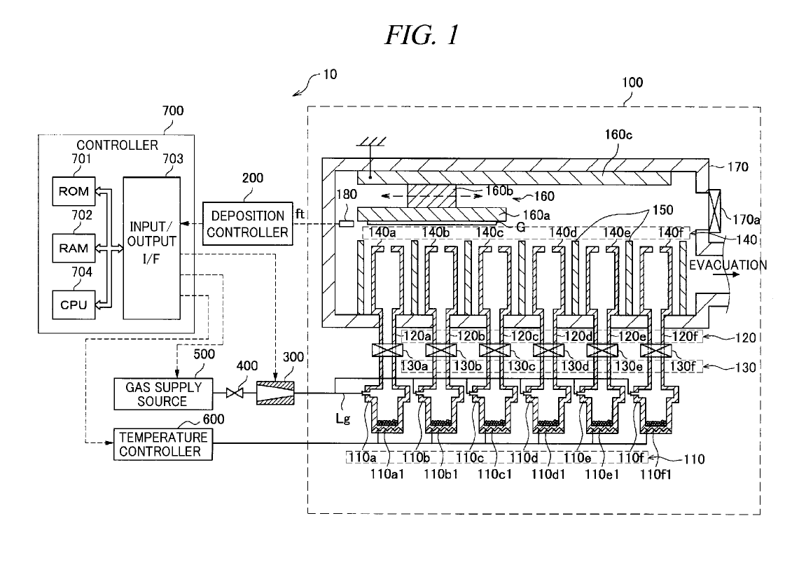

First, a 6-layer consecutive film forming system in accordance with a first embodiment of the present invention will be described with reference to FIG. 1. FIG. 1 illustrates a longitudinal cross-sectional view of an evaporating apparatus and also provides a schematic view of a 6-layer consecutive film forming system including a control apparatus that controls an evaporating apparatus.

A 6-layer consecutive film forming system 10 includes an evaporating apparatus 100, a deposition controller 200, a mass flow controller (MFC) 300, a valve 400, a gas supply source 500, a temperature controller 600 and a controller 700. The 6-layer consecutive film forming system 10 is an example of an evaporating system which manufactures an organic EL display by vapor-depositing six organic EL layers consecutively on a glass substrate (hereinafter, referred to as a substrate G) in the evaporating apparatus 100.

(Evaporating Apparatus)

The evaporating apparatus 100 is provided with first to sixth vapor deposition sources 110a to 110f, first to sixth connection pipes 120a to 120f, first to sixth valves 130a to 130f, first to sixth blowing devices 140a to 140f, seven partition walls 150, a sliding device 160 and a first processing chamber 170. In the present embodiment, the respective vapor deposition sources 110 and the respective valves 130 are installed in the atmosphere and communicated with the respective blowing devices 140 via the respective connection pipes 120. The respective blowing devices 140, the respective partition walls 150 and the sliding device 160 are installed in the first processing chamber 170 which is maintained at a desired vacuum level by a non-illustrated evacuation device.

The first to sixth vapor deposition sources 110a to 110f are crucibles having the same configuration, and different film forming materials are stored in the respective vapor deposition sources 110. First to sixth heaters 110a1 and 110f1 are embedded in bottom walls of the first to sixth vapor deposition sources 110a to 110f, respectively. By heating the respective heaters, temperatures of the respective vapor deposition sources are raised to, e.g., about 200 to 500° C., so that the respective film forming materials are evaporated.

The first to sixth connection pipes 120a to 120f are connected to the first to sixth vapor deposition sources 110a to 110f at their one ends, and they pass through the first processing chamber 170 to be connected to the first to sixth blowing devices 140a to 140f, respectively at their other ends. Further, installed respectively at the first to sixth connection pipes 120a to 120f are the first to sixth valves 130a to 130f which allow an inner space of the first processing chamber 170 to be communicated with or isolated from spaces in the respective vapor deposition sources 110 for storing the film forming materials by opening/closing operations.

The first to sixth blowing devices 140a to 140f have the same inner configuration formed in a hollow rectangular shape, and they are arranged in parallel to each other and spaced apart from each other at an equivalent interval. Film forming molecules evaporated from the respective vapor deposition sources 110 are respectively blown out from openings formed at upper centers of the respective blowing devices 140 through the respective connection pipes 120.

The partition walls 150 are installed between the respective blowing devices 140 such that the respective blowing devices 140 are separated from each other and film forming molecules blown out from the upper openings of the respective blowing devices 140 can be prevented from being mixed with film forming molecules blown out from the adjacent blowing devices 140.

The sliding device 160 includes a stage 160a, a support body 160b and a slide mechanism 160c. The stage 160a is supported by the support body 160b and electrostatically attracts the substrate G transferred through a gate valve 170a, which is installed at the first processing chamber 170, by a high voltage applied thereto from a non-illustrated high voltage power supply. The slide mechanism 160c is installed at a ceiling portion of the first processing chamber 170 and it is grounded. The slide mechanism 160c slides the substrate G attracted onto the stage 160a in a lengthwise direction of the first processing chamber 170, so that the substrate G moves in a horizontal direction slightly above the respective blowing devices 140.

A QCM (Quartz Crystal Microbalance: quartz vibrator) 180 is provided inside the first processing chamber 170. The QCM 180 is an example of a first sensor for detecting a deposition rate (D/R), i.e., a generation rate of the film forming molecules blown out from the upper openings of the respective blowing devices 140. Below, the principle of the QCM will be briefly explained.

In case that a density, an elastic modulus, a size or the like of a quartz vibrator body are varied equivalently by adhering a substance to the surface of a quartz vibrator, there occurs a variation of an electrical resonance frequency f, which is indicated by the following equation, due to the piezoelectric property of the vibrator.

f=½t(√C/ρ)

(t: thickness of a quartz piece, C: elastic constant, ρ: density)

By using this phenomenon, an infinitesimal quantity of deposits is measured quantitatively based on the variation of the resonance frequency of the quartz vibrator. A general term for the quartz vibrator designed as described above is a QCM. As can be seen from the equation, a change of the frequency is deemed to be determined based on a change of the elastic constant dependent on the adhered substance; and a thickness size of the adhered substance calculated in terms of the quartz density. Thus, the change of the frequency can be calculated in terms of the weight of the deposits.

By using such a principle, the QCM 180 outputs a frequency signal ft for detecting a film thickness adhered on the quartz vibrator (deposition rate). The deposition controller 200 is connected to the QCM 180. The deposition controller 200 receives the frequency signal ft outputted from the QCM 180 and calculates the weight of the deposits based on the change of the frequency and then calculates the deposition rate. The calculated deposition rate is used for controlling vaporization rates of the respective film forming materials stored in the respective vapor deposition sources 110, and a method for controlling the vaporization rates of the respective film forming materials will be explained later. Further, the deposition controller 200 serves as a deposition rate calculation unit that calculates a rate of a film deposited on the substrate G based on a signal outputted from the first sensor for detecting the deposition rate.

Installed at the respective vapor deposition sources 110 is a gas line Lg which passes through sidewalls of the respective vapor deposition sources 110 so that insides of the respective vapor deposition sources 110 communicate with the mass flow controller 300. The gas line Lg is connected with the gas supply source 500 via the valve 400 and supplies a nonreactive gas (e.g., an Ar gas) supplied from the gas supply source 500 to the insides of the respective vapor deposition sources. The nonreactive gas serves as a carrier gas for transporting the film forming molecules evaporated within the respective vapor deposition sources to the respective blowing devices 140.

The first to sixth heaters 110a1 to 110f1 embedded in the bottom wall of the first to sixth vapor deposition sources 110a to 110f are connected to the temperature controller 600. The temperature controller 600 controls the respective vapor deposition sources 110 where the respective heaters are embedded to have a desired temperature by controlling voltages applied to the respective heaters, so that the vaporization rates of the film forming materials are controlled. Furthermore, the first to sixth heaters 110a1 to 110f1 are examples of a temperature control mechanism installed in the evaporating apparatus 100.

A controller 700 includes a ROM 710, a RAM 720, an input/output interface (I/F) 730 and a CPU 740. The ROM 710 and the RAM 720 store therein, for example, data indicating a relationship between the frequency and the film thickness, programs for feedback-controlling the heaters, or the like. The input/output I/F 730 inputs the deposition rate calculated by the deposition controller 200.

By using such various data or programs stored in the ROM 710 and the RAM 720, the CPU 740 calculates voltages to be applied to the respective heaters 110a1 to 110f1 based on the inputted deposition rate, and transmits the result to the temperature controller 600. The CPU 740 instructs the gas supply source 500 to supply an argon gas serving as a carrier gas, and informs the mass flow controller 300 of increase or decrease amount of a flow rate of a carrier gas. Moreover, the deposition controller 200 and the controller 700 serve as a control mechanism that controls the evaporating apparatus 100.

(6-Layer Consecutive Film Forming Process)

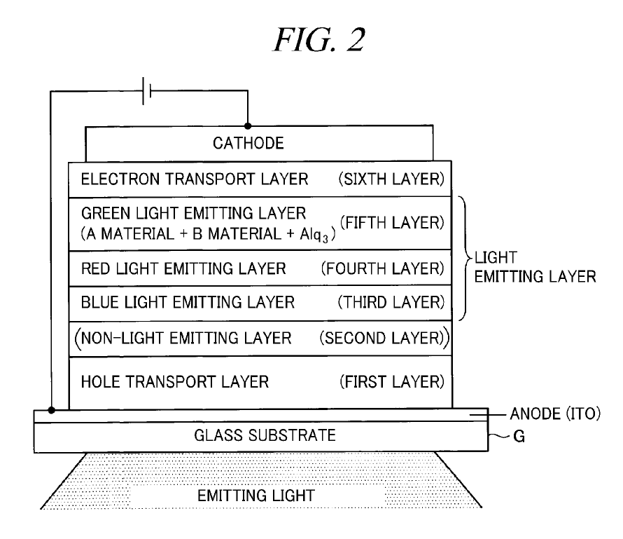

Hereinafter, a 6-layer consecutive film forming process performed in the evaporating apparatus 100 will be described briefly with reference to FIGS. 1 and 2. FIG. 2 illustrates the state of each layer deposited on the substrate G as a result of performing the 6-layer consecutive film forming process using the evaporating apparatus 100. First, while the substrate G is being moved above the first blowing device 140a at a certain rate, a film forming material blown out from the first blowing device 140a is adhered to the substrate G, so that a hole transport layer as a first layer is formed on the substrate G. Then, while the substrate G is being moved above the second blowing device 140b, a film forming material blown out from the second blowing device 140b is adhered to the substrate G, so that a non-light emitting layer (electron blocking layer) as a second layer is formed on the substrate G. Likewise, while the substrate G is being moved above the third blowing device 140c to the sixth blowing device 140f in sequence, a blue light emitting layer as a third layer, a red light emitting layer as a fourth layer, a green light emitting layer as a fifth layer and an electron transport layer as a sixth layer are formed on the substrate G by film forming materials blown out from the respective blowing devices. In this manner, in the 6-layer consecutive film forming system 10, the six layers of organic films are consecutively formed in the same processing chamber by using the evaporating apparatus 100. Accordingly, throughput can be improved, resulting in enhancement of productivity. Further, since it is unnecessary to install a plurality of different chambers (processing chambers) for respective different organic films, as in a conventional technique, scale-up of the equipment can be prevented, and equipment cost can be reduced.

(Control of a Deposition Rate)

In order to form a good quality film on a substrate by using the evaporating apparatus 100 configured as explained above, it is very important to control a deposition rate with a high accuracy. For this reason, conventionally, there has been used a method of controlling the deposition rate by a temperature control of the temperature controller 600.

However, in case of controlling the deposition rate by a temperature control, since it takes several tens of seconds or longer for the vapor deposition source 110 to actually reach a desired temperature after a temperature control mechanism such as a heater is heated, the responsiveness is poor. Further, even if the vapor deposition source 110 reaches the desired temperature several tens of seconds after the temperature control, it takes more time for the film forming material stored in the vapor deposition source 110 to stably evaporate at a desired vaporization rate. Such a poor responsiveness to the temperature control prevents a film having a good quality from being uniformly formed on the substrate G. Accordingly, the inventors of the present invention have conducted the following experiments to find other methods of controlling the deposition rate besides using the temperature control.

(Experiment 1)

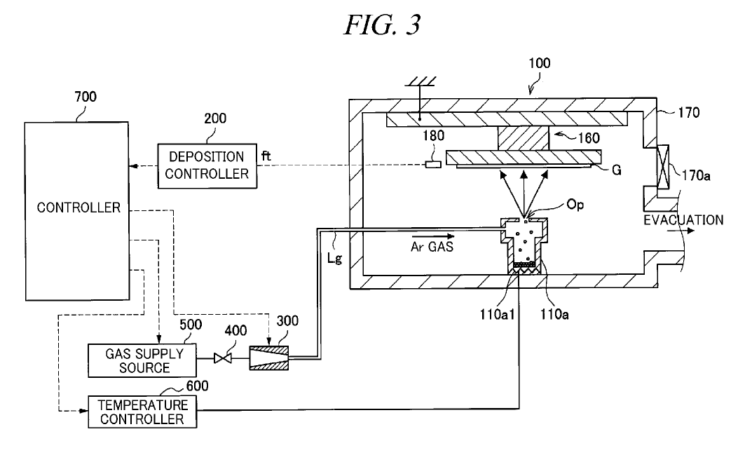

The experiments conducted by the inventors will be explained in detail with reference to FIGS. 3 to 7. First, as illustrated in FIG. 3, the inventors prepared an experimental apparatus having only one vapor deposition source 110a installed in a first processing chamber 170. The inventors stored 3 g of an organic material of Alq₃ (aluminum-tris-8-hydroxyquinoline) in a bottom portion of the vapor deposition source 110a in advance and controlled a temperature inside the first processing chamber 170 to be 310° C. During the experiment, the inventors instructed a controller 700 to control a mass flow controller 300 to increase or decrease a flow rate to be in a range of 0.5 to 20 sccm. The inventors calculated how a deposition rate of an Alq₃ organic film formed on a substrate G is varied with respect to a variation of a flow rate of an argon gas introduced into the vapor deposition source 110a based on a detected value ft of a QCM 180 by using a deposition controller 200.

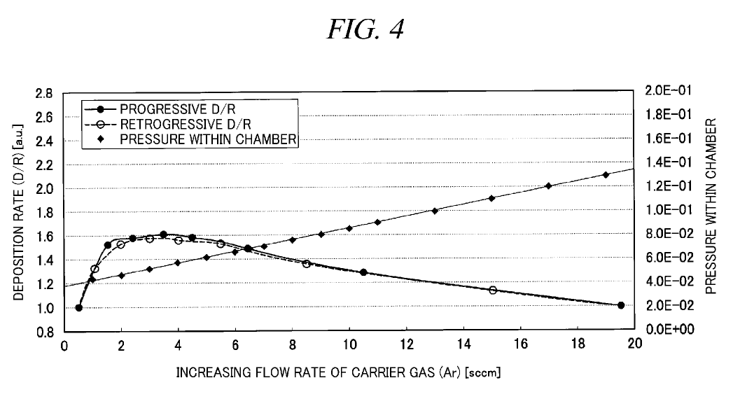

As a result, the inventors obtained a correlation between a flow rate of an argon gas and a deposition rate of an Alq₃ film, as shown in FIG. 4. In case of increasing the flow rate from 0.5 sccm to 20 sccm (progressive D/R of FIG. 4) and in case of decreasing the flow rate from 20 sccm to 0.5 sccm (retrogressive D/R), it could be seen that there is almost no influence of a hysteresis, particularly when the flow rate of the argon gas is in a range of 5 to 20 sccm. Also, it could be seen that the deposition rate varies substantially linearly in both of the cases. Accordingly, under the processing conditions of Experiment 1, the inventors found that, if the flow rate of the argon gas is in a range of 5 to 20 sccm, the deposition rate can be increased by decreasing the flow rate of the argon gas by a predetermined amount and the deposition rate can be decreased by increasing the flow rate of the argon gas by a predetermined amount.

(Experiment 2)

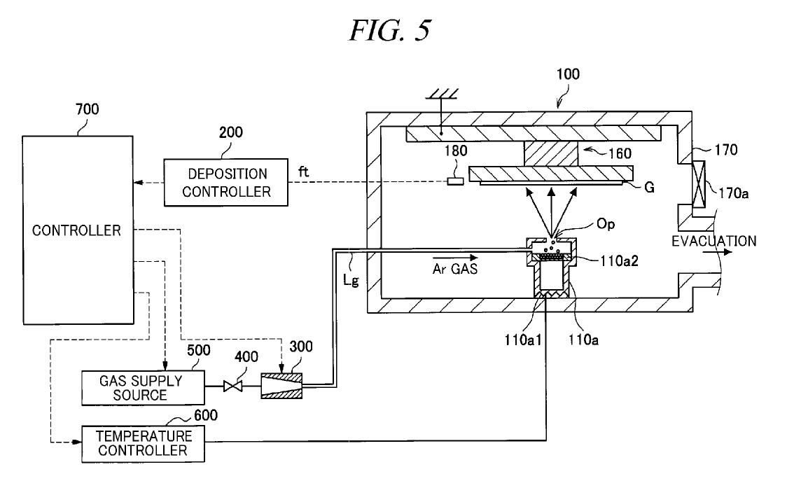

Then, the inventors conducted an experiment to find out how a correlation between a flow rate of a carrier gas and a deposition rate changes when the experiment is conducted under different processing conditions. As illustrated in FIG. 5, in Experiment 2, the inventors used the same experimental apparatus as that used in Experiment 1. Conditions different from those of Experiment 1 are a storing position of a film forming material, a kind of a film forming material and a control temperature inside a processing chamber. That is, the inventors prepared an evaporation dish 110a2 in the vicinity of a blowing opening Op of a vapor deposition source 110a, and stored 3 g of an organic material of α-NPD (diphenyl naphthyl diamine) in a recess portion of the evaporation dish 110a2, and controlled a temperature inside a first processing chamber 170 to be 300° C. The inventors instructed a controller 700 to control a mass flow controller 300 to increase or decrease a flow rate to be in a range of 0.5 to 20 sccm, and calculated a deposition rate of a α-NPD organic film by using a QCM 180 and a deposition controller 200 in the same manner as conducted in Experiment 1.

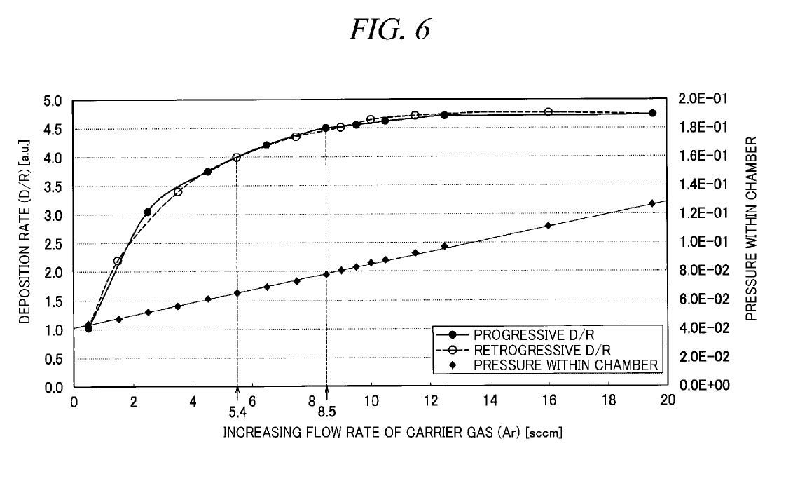

As a result, the inventors obtained a correlation between a flow rate of an argon gas and a deposition rate of an Alqₐ film, as shown in FIG. 6. From this correlation, in cases of progressive D/R and retrogressive D/R, the inventors found out that there is almost no influence of a hysteresis, particularly when the flow rate of the argon gas is in a range of 5 to 20 sccm. Also, it could be seen that the deposition rate varies substantially linearly in both of the cases. Accordingly, under the processing conditions of Experiment 2, the inventors found that, if the flow rate of the argon gas is in a range of 5 to 20 sccm, the deposition rate can be increased by increasing the flow rate of the argon gas by a predetermined amount and the deposition rate can be decreased by decreasing the flow rate of the argon gas by a predetermined amount.

(Experiment 3)

In addition, the inventors conducted an experiment to find out how a correlation between a flow rate of a carrier gas and a deposition rate changes when the experiment is conducted under different processing conditions. The inventors used the same experimental apparatus used in Experiment 2 as illustrated in FIG. 5, and stored 3 g of an organic material of Alqₐ in the recess portion of the evaporation dish 110a2, and controlled a temperature inside the first processing chamber 170 to be 300° C. The inventors instructed the controller 700 to control the mass flow controller 300 to increase or decrease a flow rate to be in a range of 0.5 to 20 sccm, and calculated a deposition rate of a Alqₐ organic film by using the QCM 180 and the deposition controller 200 in the same manner as conducted in Experiments 1 and 2.

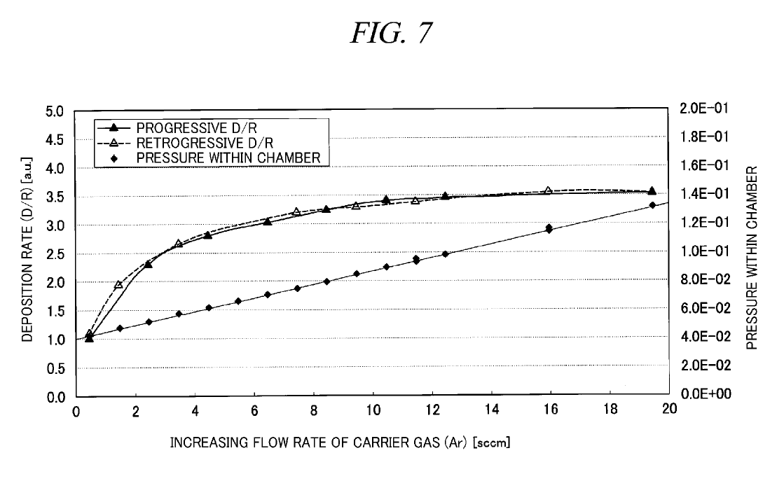

As a result, the inventors obtained a correlation between a flow rate of an argon gas and a deposition rate of an Alq₃ film, as shown in FIG. 7. From this correlation, in cases of progressive D/R and retrogressive D/R, the inventors found out that there is almost no influence of a hysteresis, particularly when the flow rate of the argon gas is in a range of 5 to 20 sccm. Also, it could be seen that the deposition rate varies substantially linearly in both of the cases. Accordingly, under the processing conditions of Experiment 3, the inventors found that the deposition rate can be increased by increasing the flow rate of the argon gas by a predetermined amount and the deposition rate can be decreased by decreasing the flow rate of the argon gas by a predetermined amount.

Furthermore, according to the result of Experiment 1 shown in FIG. 4, if the flow rate of the carrier gas is increased, the deposition rate is decreased. However, according to the results of Experiment 2 shown in FIG. 6 and Experiment 3 shown in FIG. 7, if the flow rate of the carrier gas is increased, the deposition rate is increased. Such an inverse correlation between the results is caused by a difference in the processing conditions when the data were obtained.

Based on these experiment results, in order to obtain a desired deposition rate by accurately controlling a flow rate of the argon gas while taking into consideration that the processing conditions of the evaporating apparatus 100 exert an influence upon the control of the flow rate of the argon gas, the inventors stored the data showing the correlations between the flow rates of the gas and the deposition rates of the organic film in FIGS. 4, 6 and 7, and the data are linked with the processing conditions at the time the data were obtained. Here, the processing conditions may include at least one of information on a material of the vapor deposition source 110a, a kind of a film forming material stored in the vapor deposition source 110a and a position of the film forming material stored in the vapor deposition source 110a. By using plural patterns of the correlations between the flow rate of the carrier gas and the deposition rate which are stored as described above, the deposition rate is controlled by adjusting the flow rate of the carrier gas in the 6-layer consecutive film forming system 10 in accordance with the present embodiment. A detailed operation thereof will be described after explaining functional configurations of the controller 700.

(Functional Configurations of the Controller)

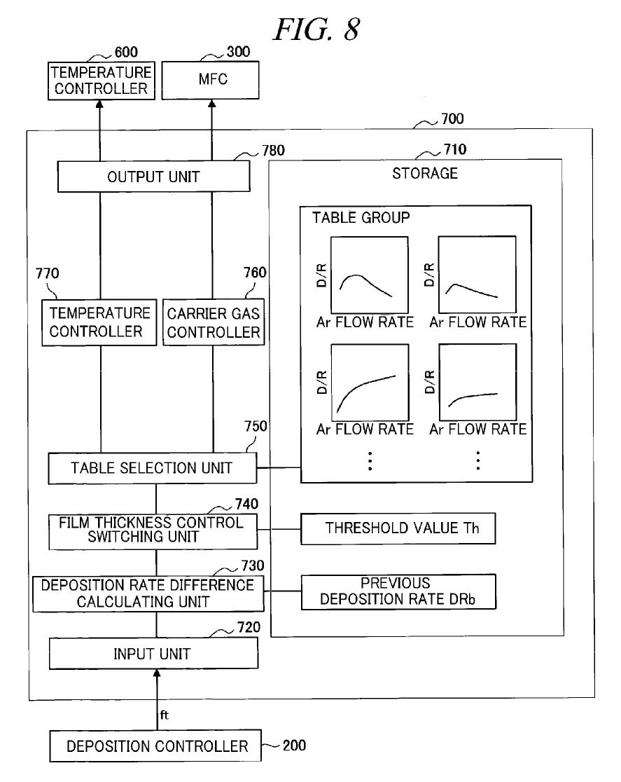

As illustrated in FIG. 8, the controller 700 has functions represented by functional blocks of a storage 710, an input unit 720, a deposition rate difference calculating unit 730, a film thickness control switching unit 740, a table selection unit 750, a carrier gas controller 760, a temperature controller 770 and an output unit 780.

The storage 710 stores a table group including a plurality of tables of FIGS. 4, 6 and 7 showing the correlations between the deposition rates and the flow rates of the carrier gas, which are data collected through a number of experiments conducted by the inventors as described above. The storage 710 also stores a predetermined threshold value Th and a deposition rate DRb calculated previously.

The input unit 720 inputs a deposition rate calculated by the deposition controller 200 at intervals of predetermined time. The deposition rate difference calculating unit 730 acquires a difference between the deposition rate inputted at intervals of predetermined time and a target deposition rate.

If an absolute value of the difference of the deposition rates acquired by the deposition rate difference calculating unit 730 is equal to or less than the predetermined threshold value Th, the film thickness control switching unit 740 controls the deposition rate by adjusting the flow rate of the carrier gas. Meanwhile, if an absolute value of the difference is greater than the predetermined threshold value Th, the film thickness control switching unit 740 switches the control method such that the deposition rate is controlled by adjusting the temperature in combination with other adjustment.

Such a switching method is found from results of the following experiment conducted by the inventors. That is, the inventors found out that, in order to accurately control the deposition rate by adjusting the flow rate of the carrier gas, it is good when the difference between the calculated deposition rate and the target deposition rate is relatively small.

The inventors found that, in order to accurately control the deposition rate by adjusting the flow rate of the carrier gas, it is desirable that the maximum value of the difference (deviation) is particularly about 5 times or less, as shown in FIGS. 4, 6 and 7. Considering this, in the present embodiment, the predetermined threshold value stored in the storage 710 is set such that the maximum value of the difference between the target deposition rate and the deposition rate obtained by the deposition controller 200 is about 5 times during the film forming control by controlling the flow rate of the carrier gas.

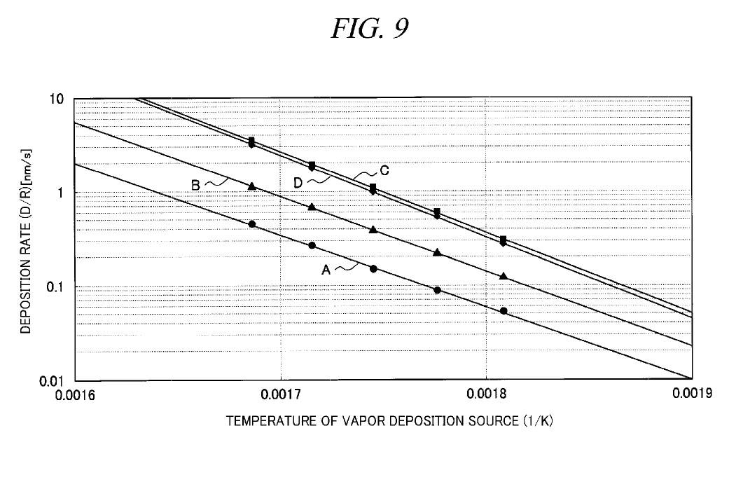

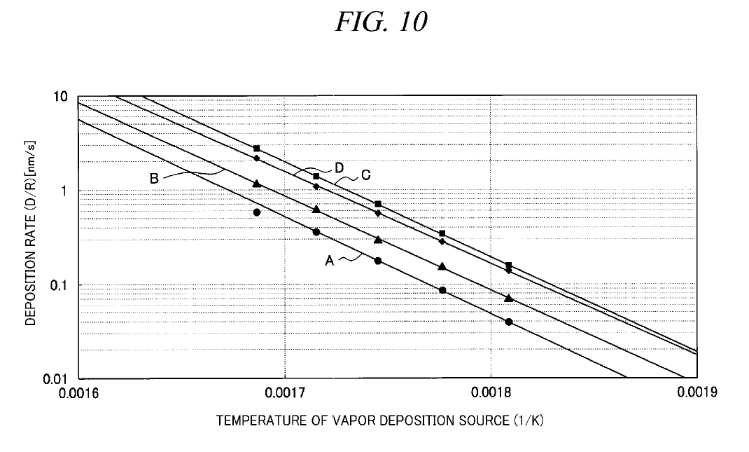

Meanwhile, it was found that, if the difference is relatively large, it is desirable to control the deposition rate by adjusting the temperature in combination with other adjustment, as illustrated in FIGS. 9 and 10. Here, FIG. 9 shows a correlation between a reciprocal (1/K) of an absolute temperature inside a vapor deposition source and a deposition rate (nm/s). Further, FIG. 10 shows a correlation between a reciprocal (1/K) of an absolute temperature inside a vapor deposition source and a deposition rate (nm/s) in case that an organic material α-NPD used in FIG. 9 is changed to an organic material Alq₃. As illustrated in FIGS. 9 and 10, an evaporation amount (deposition rate ν) is expressed as ν=Aexp(−B/T) (here, A and B are constants dependent on the material or the apparatus, and T is an absolute temperature). Further, it can be seen that even if vapor depositions are performed under various processing conditions A to D, constant relationships between the temperatures and the deposition rates are found, and the deposition rate can be accurately controlled by adjusting the temperature in each case. Furthermore, it can be seen that the deposition rate can be changed up to about 100 times by controlling the temperature.

Based on the processing conditions, the table selection unit 750 selects a desired table satisfying the processing condition from the plurality of the tables stored in the storage 710. Here, the processing conditions may include at least one condition of a shape of the vapor deposition source 110, a material of the vapor deposition source 110, a kind of a film forming material stored in the vapor deposition source 110 and a position of the film forming material stored in the vapor deposition source 110.

The carrier gas controller 760 controls the flow rate of the carrier gas to obtain a desired deposition rate based on the target deposition rate and the deposition rate obtained by the deposition controller 200, with reference to data indicating a relationship between the deposition rate and the flow rate of the carrier gas stored in a table selected by the table selection unit 750.

The temperature controller 770 controls the temperature to obtain a desired deposition rate based on the target deposition rate and the deposition rate obtained by the deposition controller 200, with reference to, e.g., data indicating a relationship between the deposition rate and the temperature shown in FIG. 9 or FIG. 10.

When the deposition rate is controlled by the flow rate of the carrier gas, the output unit 780 outputs a signal for controlling the mass flow controller (MFC) 300 to the mass flow controller 300 such that the flow rate of the carrier gas is adjusted at a desired flow rate. Meanwhile, when the deposition rate is controlled by the temperature, the output unit 780 outputs, to the temperature controller 600, a signal for adjusting a voltage (or a voltage variation) applied to the heater to be a desired voltage. Further, each function of the controller 700 explained above can be actually performed by, e.g., the CPU 740 which executes a program including a process sequence for implementing each function.

(Operation of the Controller)

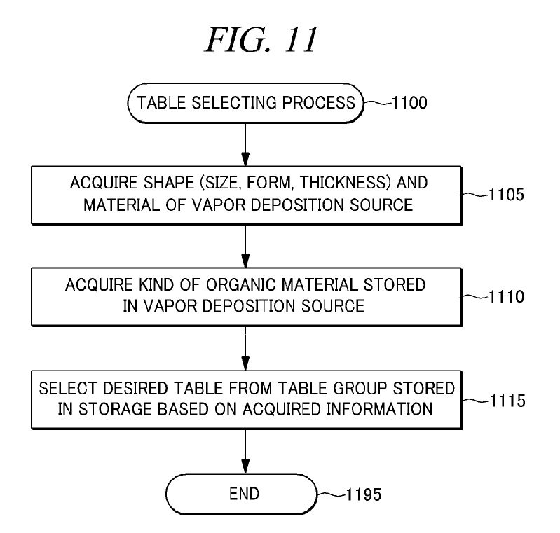

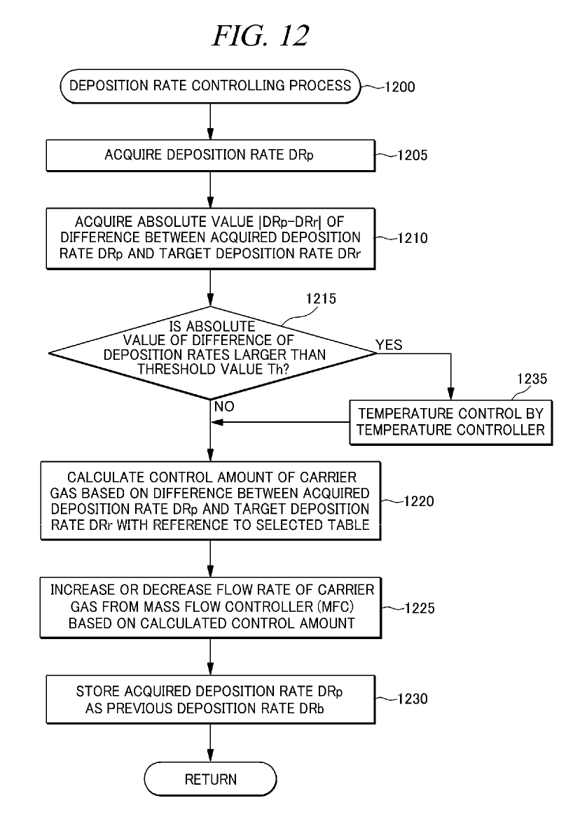

Hereinafter, an operation of the controller 700 will be explained with reference to FIGS. 11 and 12. FIG. 11 is a flowchart showing a process of selecting a table satisfying a film formation condition from the plurality of tables stored in the storage 710. FIG. 12 is a flowchart showing a process of controlling a deposition rate by controlling a flow rate of a carrier gas or a temperature of the vapor deposition source.

(Table Selecting Process)

The table selecting process is started from step 1100 of FIG. 11, and the table selection unit 750 acquires a shape (a size, a form, a thickness, or the like) of the vapor deposition source 110 or a material of the vapor deposition source 110 in step 1105, and acquires a kind of an organic material stored in the vapor deposition source 110 in step 1110. Thereafter, in step 1115, the table selection unit 750 selects a table satisfying the processing conditions from the table group stored in the storage 710 based on the acquired information (i.e., process conditions in the evaporating apparatus 100). Then, the process proceeds to step 1195 and ends.

The table selecting process stated above may be performed just once before one sheet of the substrate G is processed until the processing conditions in the evaporating apparatus 100 are not changed (alternatively, until the changed processing conditions do not have an influence upon the control of the flow rate of the carrier gas). On the other hand, a process of controlling a deposition rate to be explained hereafter with reference to FIG. 12 may be performed, e.g., at each time a sheet of the substrate G is processed or at intervals of predetermined time. Further, before the deposition rate controlling process is started, the inside of the first processing chamber 170 is maintained at a predetermined temperature according to the processing conditions.

(Deposition Rate Controlling Process)

The deposition rate controlling process is started from step 1200 of FIG. 12. When the process is progressed to step 1205, the deposition rate difference calculating unit 730 acquires a (present-time) deposition rate DRp calculated by the deposition controller 200. In step 1210, obtained is an absolute value |DRp−DRr| of a deviation between the acquired deposition rate DRp and a target deposition rate (DRr).

Then, in step 1215, the film thickness control switching unit 740 determines whether the absolute value of the deviation of the deposition rates is larger than a predetermined threshold value Th. If the absolute value of the deviation of the deposition rates is equal to or smaller than the predetermined threshold value Th, the process proceeds to step 1220. Then, the carrier gas controller 760 calculates a control amount of the carrier gas based on the difference (deviation) between the present-time deposition rate and the target deposition rate with reference to the selected table.

For example, if the table of FIG. 6 is currently selected and the acquired deposition rate DRp is 4.5 and the target deposition rate DRb is 4.0, a control flow rate of the argon gas with respect to the deviation between the present-time deposition rate and the target deposition rate is 3.1 sccm. At this time, the process proceeds to step 1225, and the carrier gas controller 760 generates a control signal for increasing or decreasing the flow rate of the argon gas blown out from the mass flow controller MFC 300 based on the calculated flow rate. Then, the output unit 780 outputs the control signal to the mass flow controller 300. For instance, in the above-stated example, the carrier gas controller 760 generates a control signal to reduce the flow rate of the argon gas by 3.1 sccm, and outputs the generated control signal to the output unit 780. Finally, in step 1230, the storage 710 stores the acquired deposition rate DRp as a previous deposition rate DRb. Then, the process proceeds to step 1295 and ends.

Meanwhile, in step 1215, if the absolute value of the deviation of the deposition rate is larger than the predetermined threshold value Th, the process proceeds to step 1235. Then, the temperature controller 770 acquires a control amount of the temperature required to obtain a desired deposition rate based on the target deposition rate and the deposition rate acquired by the deposition controller 200, with reference to the data indicating the relationship between the deposition rate and the temperature as shown in FIG. 9 or FIG. 10. Further, the temperature controller 770 calculates a voltage applied to the heater according to the acquired control amount of the temperature. The output unit 780 outputs, to the temperature controller 600, a control signal for applying the calculated voltage to the heater. Then, the carrier gas flow rate control (steps 1220 to 1230) is performed, and the process proceeds to step 1295 and ends.

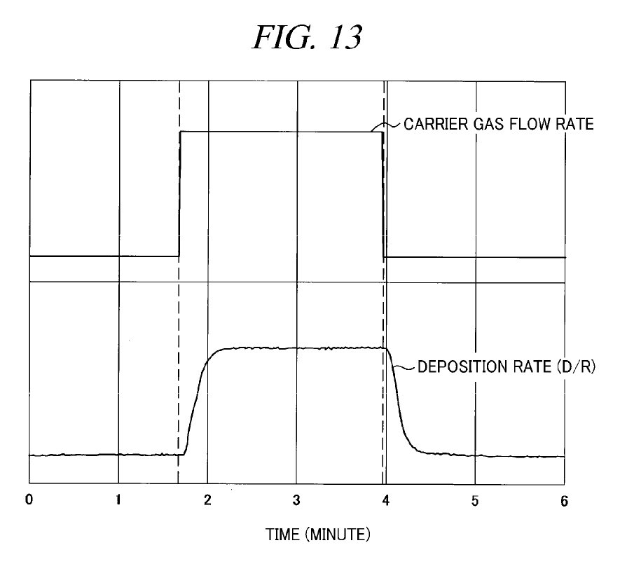

The inventors conducted an experiment on an effect of controlling the flow rate of the carrier gas explained in steps 1220 and 1225, and obtained a result as shown in FIG. 13. In this experiment, the inventors varied the flow rate of the carrier gas in a pulse shape as shown in an upper side of FIG. 13. At this time, the deposition rate follows-up the changes of the flow rate of the gas with a high accuracy after several seconds to several tens of seconds as shown in a lower side of FIG. 13. As a result, the inventors proved that, in the 6-layer consecutive film forming system 10 in accordance with the present embodiment, a small deviation of the deposition rate from the target value can be quickly corrected by controlling the flow rate of the carrier gas, and a uniform film having a good quality can be formed on the substrate G.

In particular, an organic EL material has a low heat-resistance and thus easily decomposed. For example, even if a temperature of the vapor deposition source is raised only by 10° C. from 250° C. to increase a deposition rate, many kinds of organic EL materials are decomposed and their properties are changed, so that a desired performance thereof can not be obtained. Under this circumstance, it is important to control the deposition rate by adjusting the flow rate of the carrier gas instead of adjusting the temperature to follow-up a small change of the deposition rate, so that the deposition rate can be quickly controlled to be a desired rate without changing the property of the film forming material.

Further, in accordance with the deposition rate control adjusting the flow rate of the carrier gas as described above, there is no need for a new device such as a vacuum valve having a high-temperature resistance, so that the mass flow controller 300 already connected to the gas supply source 500 may be used. Accordingly, the deposition rate can be accurately controlled without a risk of a high cost problem which can be caused when the number of the required parts is increased or a risk of a re-condensation of the film forming molecules in the valve, which can be caused when the amount of the film forming molecules is controlled by using the valve.

Meanwhile, when the difference in the deposition rates is relatively large, it is difficult to appropriately adjust the deposition rate to be the target value only by controlling the flow rate of the carrier gas. Therefore, in the present embodiment, when the deposition rate is greatly changed, the deposition rate is controlled by adjusting the temperature in combination with other adjustment. In this way, in the present embodiment, the control of the temperature and the control of the flow rate of the carrier gas are switched depending on the degree of the change in the deposition rates. Thus, the deposition rate can be accurately controlled by appropriately following-up a great change or a small change in the deposition rates.

Further, in the 6-layer consecutive film forming system 10 in accordance with the present embodiment, a desired table is selected from the plurality of tables stored in the storage 710. To be specific, an optimum table that corresponds to a processing condition or a state of the vapor deposition source 110 actually used for manufacturing the product is selected from pre-stored data. Accordingly, a control amount of the flow rate of the carrier gas can be optimized depending on a material or a device actually used in the manufacturing process, and thus the deposition rate can be controlled more accurately.

Furthermore, in the present embodiment, the deposition rate is controlled by completely switching to the control of the flow rate of the carrier gas or to the control of the temperature depending on the determination of step 1215. However, if a difference between the target deposition rate DRr and the deposition rate DRp obtained by the deposition controller 200 is equal to or larger than the predetermined threshold value Th in the determination of step 1215, the deposition rate can be controlled by adjusting the temperature of the evaporating apparatus 100 by the temperature controller 770 while adjusting the flow rate of the carrier gas by the carrier gas controller 760.

### Second Embodiment

Hereinafter, a 6-layer consecutive film forming system 10 in accordance with a second embodiment will be explained. In the 6-layer consecutive film forming system 10 in accordance with the second embodiment, respective vapor deposition sources 110 and respective valves 130 are installed in a second processing chamber, and respective QCMs are installed in the vicinity of the respective vapor deposition sources 110. This configuration is different from that of the 6-layer consecutive film forming system 10 in accordance with the first embodiment which does not have the second processing chamber and the QCM for each vapor deposition source 110. Accordingly, the 6-layer consecutive film forming system 10 in accordance with the present embodiment will be explained, focusing on such a difference.

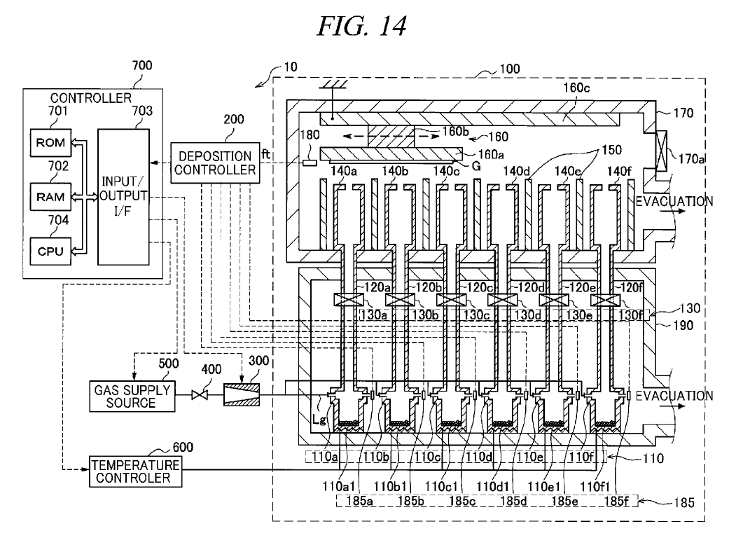

As illustrated in FIG. 14, an evaporating apparatus 100 in accordance with the present embodiment is provided with a second processing chamber 190 in addition to a first processing chamber 170. In the second processing chamber 190, first to sixth vapor deposition sources 110a to 110f and first to sixth valves 130a to 130f are installed. The second processing chamber 190 is evacuated to a desired vacuum level by a non-illustrated evacuation device.

Installed at upper sidewalls of the first to sixth vapor deposition sources 110a to 110f are exhaust pipes passing through the sidewalls thereof, and installed in the vicinities of openings of the exhaust pipes are first to sixth QCMs 185a to 185f, respectively. The first to sixth QCMs 185a to 185f output respective frequency signals to detect a thickness of a deposit, which is exhausted from the openings of respective exhaust pipes and then adhered to a quartz vibrator. The QCM 185 is one example of a second sensor.

A deposition controller 200 receives the frequency signals detected by the respective QCMs 185. The deposition controller 200 calculates respective vaporization rates of plural film forming materials based on the frequency signals outputted from the respective QCMs 185.

An input unit 720 of a controller 700 inputs the vaporization rates of the film forming materials in the respective vapor deposition sources 110 calculated by the deposition controller 200. A carrier gas controller 760 calculates, for each vapor deposition source, a control amount of the flow rate of the carrier gas supplied to each vapor deposition source 110 based on a target vaporization rate and the vaporization rate of each film forming material calculated by the deposition controller 200 with reference to a relationship between the deposition rate and the flow rate of the carrier gas shown in a table stored in a storage 710. Then, each flow rate of the carrier gas introduced into each vapor deposition source 110 is separately controlled according to the obtained control amount for each vapor deposition source.

In a case where the film forming material is a sublimation material, the state of the film forming material stored in the vapor deposition source may be changed suddenly during its vaporization in the vapor deposition source, as compared to a case where the film forming material is a melting material. In this case, a contact state between the vapor deposition source and the film forming material is suddenly changed, so that the vaporization rate of the film forming material is changed, resulting in a change of the deposition rate.

However, in the 6-layer consecutive film forming system 10 in accordance with the present embodiment, as described above, the flow rate of the carrier gas introduced into each vapor deposition source is controlled for each vapor deposition source based on the target vaporization rate and the vaporization rate for each film forming material stored in the plurality of vapor deposition sources 110 arranged in the evaporating apparatus 100. Accordingly, the vaporization rate of the film forming material can be accurately controlled for each vapor deposition source depending on a storing state of the film forming material. As a result, a good quality film can be formed uniformly on the substrate G.

### Modified Embodiment

In the embodiments described above, the flow rate of the carrier gas is controlled based on the difference between the target deposition rate and the deposition rate calculated by the deposition controller 200. Alternatively, the flow rate of the carrier gas may be controlled based on a difference between a deposition rate calculated one time before (or two or more times before) by the deposition controller 200 and a deposition rate calculated at the present time by the deposition controller 200.

In this case, the carrier gas controller 760 feedback-controls the flow rate of the carrier gas to obtain a desired deposition rate based on the deposition rate obtained one time before (or two or more times before) by the deposition controller 200 and the deposition rate obtained at the present time by the deposition controller 200.

Accordingly, the flow rate of the carrier gas is controlled based on the deposition rate obtained one time before (or two or more times before) and the deposition rate obtained at the present time. As described above, after conducting many experiments, the inventors found out that there is a correlation between the flow rate of the carrier gas and the deposition rate. Accordingly, it may be possible to calculate every time whether to increase or decrease the amount of the carrier gas based on a difference between the deposition rate calculated previously and the deposition rate calculated at the present time. Further, a feedback control such as a PID (Proportional Integral Derivative) control, a fuzzy control or an H∞ (H-infinity) control can be used as such a control. As a result, a good quality film can be uniformly formed on the substrate G by accurately controlling the deposition rate by using the carrier gas.

Further, in the above-stated modified embodiment, the control amount of the flow rate of the carrier gas may be calculated based on a difference between the deposition rate obtained one time before and the deposition rate obtained at the present time or a difference between the deposition rate obtained two or more times before and the deposition rate obtained at the present time.

According to each embodiment and the modified embodiment described above, the deposition rate can be accurately controlled by adjusting the flow rate of the carrier gas.

Further, in each embodiment and the modified embodiment described above, the argon gas is used as the carrier gas. However, the carrier gas is not limited to the argon gas, and may be a nonreactive gas such as a helium gas, a krypton gas or a xenon gas.

Furthermore, the size of the glass substrate capable of being processed by the evaporating apparatus 100 in each embodiment may be about 730 mm×920 mm or greater. For example, the evaporating apparatus 100 may perform a consecutive film forming process on a G4.5 substrate size of about 730 mm×920 mm (in-chamber size: about 1000 mm×1190 mm) or a G5 substrate size of about 1100 mm×1300 mm (in-chamber size: about 1470 mm×1590 mm). Moreover, the target object processed by the evaporating apparatus 100 in each embodiment may include a silicon wafer having a diameter of 200 mm or 300 mm besides the glass substrate having the above-stated size.

Further, as another example of the first sensor and the second sensor used for calculating the deposition rate in each embodiment, there can be employed an interferometer (e.g., a laser interferometer) for detecting a film thickness of a target object by, e.g., irradiating light outputted from a light source onto a top surface and a bottom surface of a film formed on the target object and observing and analyzing an interference fringe generated by a difference in optical paths of the two reflected beams. Alternatively, there can be employed a method of calculating the film thickness from spectrum information of irradiated light having a broadband wavelength to calculate the deposition rate.

In the above-described embodiment, the operations of the respective parts are interrelated and can be substituted with a series of operations in consideration of such interrelation. By the substitution, the embodiment of the control apparatus of the evaporating apparatus can be used as an embodiment of a control method of the evaporating apparatus.

Further, by substituting the operation of each part with the process of each part, the embodiment of the control method of the evaporating apparatus can be used as an embodiment of a program for controlling the evaporating apparatus and an embodiment of a computer readable storage medium storing the program.

Though the embodiments of the present invention have been explained with reference to the accompanying drawings, it is clear that the present invention is not limited thereto. It would be understood by those skilled in the art that various changes and modifications may be made within the scope of the claims and included in the scope of the present invention.

For example, in the evaporating apparatus 100 in accordance with the above-described embodiment, an organic EL material in the form of powder (solid) is used as the film forming material, and an organic EL multi-layer film forming process is performed on the substrate G. However, the evaporating apparatus in accordance with the present invention can also be employed in a MOCVD (Metal Organic Chemical Vapor Deposition) method for depositing a thin film on a target object by decomposing a film forming material vaporized from, e.g., a liquid organic metal on the target object heated up to about 500 to 700° C.

In addition, the control device of the evaporating apparatus in accordance with the present invention can be used not only for controlling the evaporating apparatus for forming the organic film but also for controlling the evaporating apparatus for manufacturing a liquid crystal display.

1. A control device of an evaporating apparatus in which a film forming material evaporated from a vapor deposition source is transported by a carrier gas and a film forming process is performed on a target object by the transported film forming material in a desired vacuum state, the device comprising:
a storage that stores a table indicating a relationship between a deposition rate and a flow rate of the carrier gas;
a deposition rate calculation unit that calculates a deposition rate for the target object based on a signal outputted from a first sensor for detecting a deposition rate; and
a carrier gas controller that controls a flow rate of the carrier gas to obtain a desired deposition rate based on a target deposition rate and the deposition rate obtained by the deposition rate calculation unit, with reference to data indicating a relationship between a deposition rate and a flow rate of the carrier gas shown in the table stored in the storage.

2. The device of claim 1, wherein a mass flow controller that controls a flow rate of a gas is installed in the evaporating apparatus, and
the carrier gas controller controls a flow rate of the carrier gas introduced into the vapor deposition source by controlling the mass flow controller.

3. The device of claim 1, wherein the storage stores a plurality of different tables,
a table selection unit that selects a desired table from the plurality of tables stored in the storage based on a processing condition is further provided, and
the carrier gas controller controls a flow rate of the carrier gas, with reference to a table selected by the table selection unit.

4. The device of claim 3, wherein the processing condition includes at least one of a shape of the vapor deposition source, a material of the vapor deposition source, a kind of a film forming material stored in the vapor deposition source and a position of the film forming material stored in the vapor deposition source.

5. The device of claim 1, wherein the carrier gas controller controls a deposition rate by adjusting a flow rate of the carrier gas if a difference between the target deposition rate and the deposition rate obtained by the deposition rate calculation unit is smaller than a predetermined threshold value.

6. The device of claim 5, further comprising:
a temperature controller that controls a temperature of the evaporating apparatus; and
a film thickness control switching unit that switches a control of a deposition rate to a control using the carrier gas controller or a control using both the carrier gas controller and the temperature controller, and
wherein the film thickness control switching unit switches a control of a deposition rate to a control using the temperature controller to adjust a temperature of the evaporating apparatus and the carrier gas controller to adjust a flow rate of the carrier gas if the difference between the target deposition rate and the deposition rate obtained by the deposition rate calculation unit is equal to or greater than the predetermined threshold value.

7. The device of claim 5, wherein the predetermined threshold value is set such that a maximum value of the difference between the target deposition rate and the deposition rate obtained by the deposition rate calculation unit is about 5 times the predetermined threshold value or less during a control by the carrier gas controller.

8. The device of claim 1, wherein a plurality of vapor deposition sources is installed,
the deposition rate calculation unit calculates respective vaporization rates of a plurality of film forming materials based on signals outputted from a plurality of second sensors for respectively detecting the vaporization rates of the film forming materials stored in the plurality of vapor deposition sources in a desired vacuum state, and
the carrier gas controller controls, for each vapor deposition source, a flow rate of the carrier gas introduced into each vapor deposition source based on a target vaporization rate and a vaporization rate of each film forming material obtained by the deposition rate calculation unit, with reference to data indicating a relationship between a deposition rate and a flow rate of the carrier gas shown in the table stored in the storage.

9. The device of claim 1, wherein the apparatus controls a deposition rate of the evaporating apparatus in which an organic EL film or an organic metal film is formed on the target object by a vapor deposition by using an organic EL film forming material or an organic metal film forming material as the film forming material.

10. A control device of an evaporating apparatus in which a film forming material evaporated from a vapor deposition source is transported by a carrier gas and a film forming process is performed on a target object by the transported film forming material in a desired vacuum state, the device comprising:
a deposition rate calculation unit that calculates a deposition rate for the target object based on a signal outputted from a first sensor for detecting a deposition rate; and
a carrier gas controller that feedback-controls a flow rate of the carrier gas to obtain a desired deposition rate based on a deposition rate obtained one time before (or two or more times before) by the deposition rate calculation unit and a deposition rate obtained at the present time by the deposition rate calculation unit.

11. A control method of an evaporating apparatus in which a film forming material evaporated from a vapor deposition source is transported by a carrier gas and a film forming process is performed on a target object by the transported film forming material in a desired vacuum state, the method comprising:
storing, in a storage, a table indicating a relationship between a deposition rate and a flow rate of the carrier gas;
calculating a deposition rate for the target object based on a signal outputted from a first sensor for detecting a vaporization rate of the film forming material; and
controlling a flow rate of the carrier gas to obtain a desired deposition rate based on the calculated deposition rate and a target deposition rate, with reference to data indicating a relationship between a deposition rate and a flow rate of the carrier gas shown in the table stored in the storage.
